(19) United States
(12) Patent Application Publication
(10) Pub. No.: US 2007/0010035 A1
(43) Pub. Date: Jan. 11, 2007

(54) LIGHT EMITTING DIODE AND MANUFACTURING METHOD THEREOF

(75) Inventors: Cheng-Yi Liu, Taoyuan (TW); Shih-Chieh Hsu, Taoyuan (TW); Ching-Liang Lin, Taoyuan (TW); Yong-Syun Lin, Taoyuan (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: National Central University, Taoyuan (TW)

(21) Appl. No.: 11/425,149

(22) Filed: Jun. 20, 2006

(30) Foreign Application Priority Data
Jul. 11, 2005 (TW) 94123324

(51) Int. Cl. H01L 21/00

(52) U.S. Cl. 438/22

(57) ABSTRACT

A method for fabricating a light emitting diode (LED) is provided. First, a first type doped semiconductor layer, an emitting layer and a second type doped semiconductor layer are sequentially formed on an epitaxy substrate. Then, a first transparent conductive layer is formed on the second type doped semiconductor layer. Next, a substitution substrate having a second transparent conductive layer formed thereon is provided. Then, a wafer bonding process is performed on the epitaxy substrate and the substitution substrate, so as to bond the first transparent conductive layer and the second transparent conductive layer. Finally, the epitaxy substrate is removed. As mentioned above, an LED with better reliability is fabricated according to the method provided by the present invention. Moreover, the present invention further provides an LED.

### CROSS-REFERENCE TO RELATED APPLICATION

This application claims the priority benefit of Taiwan application serial no. 94123324, filed on Jul. 11, 2005. All disclosure of the Taiwan application is incorporated herein by reference.

### BACKGROUND OF THE INVENTION

1. Field of the Invention

The present invention relates to a diode and a manufacturing method thereof, and more particularly, to a light emitting diode (LED) and a method for manufacturing the same.

2. Description of the Related Art

Recently, the LED fabricated with the compound semiconductor material containing GaN, such as GaN, AlGaN and InGaN is very popular. The group IIIA nitride mentioned above is a material with a wide energy band gap, and the range of the wavelength of its emitting light is from the ultraviolet light to the red light, thus it covers nearly the whole range of the visible light band. In addition, comparing to the conventional light bulb, since the LED is advantageous in the characteristics of having a smaller size, a longer life time, needing a lower driving voltage/current, durability, mercury-free (i.e. no industrial pollution) and better light-emitting efficiency (i.e. saving more electric power), the LED has been widely applied in the industry.

FIG. 1 is a schematic sectional view of a conventional LED. Referring to FIG. 1, the conventional LED 100 comprises an aluminum oxide (Al₂O₃) substrate 110, a doped semiconductor layer 122, an emitting layer 124, and a doped semiconductor layer 126. Wherein, the doped semiconductor layer 122 is disposed on the aluminum oxide substrate 110. The emitting layer 124 is disposed on a part of the doped semiconductor layer 122, and the doped semiconductor layer 126 is disposed on the emitting layer 124. It is to be noted that the type of the doped semiconductor layer 122 is different from the type of the doped semiconductor layer 126. For example, if the doped semiconductor layer 122 is a p-type doped semiconductor layer, the doped semiconductor layer 126 should be an n-type doped semiconductor layer.

Specifically, the contact pads 132 and 134 are usually disposed on the doped semiconductor layer 126 and on a part of the doped semiconductor layer 122 that is not covered by the doped semiconductor layer 124. In addition, the contact pads 132 and 134 are usually made of a metal material. It is to be noted that the conventional LED 100 is electrically connected to a circuit board or other carrier (not shown) by the wire boding technique or a flip chip bonding technique, and the contact pads 132 and 134 are used as the contact points for electrical connection.

In the conventional LED 100 mentioned above, since the heat dissipation of the aluminum oxide substrate 110 is rather poor, after a long period of light emitting, its internal temperature is gradually increased, which gradually degrades the light-emitting efficiency of the emitting layer 124. In addition, since a crowding effect is occurred on the periphery of the contact pads 132 and 134 when the components are driven, if the local current is too high, the contact pads 132 and 134 or the neighboring doped semiconductor layer 122 and the doped semiconductor layer 126 may be damaged, which fails the normal function of the conventional LED 100.

In addition, a second conventional LED is described in greater detail with referring to FIG. 2 hereinafter.

FIG. 2 is a schematic sectional view of another conventional LED. Referring to FIG. 2, the conventional LED 200 comprises a conductive substrate 210, a doped semiconductor layer 222, an emitting layer 224 and a doped semiconductor layer 226. Wherein, the doped semiconductor layer 222 is disposed on the conductive substrate 210. The emitting layer 224 is disposed between the doped semiconductor layer 222 and the doped semiconductor layer 226.

Similarly, a contact pad 232 is usually disposed on the doped semiconductor layer 226, and the purpose of the contact pad 232 is the same as the contact pad 132 shown in FIG. 1. However, the conductive substrate 210 has a good electrical conductive characteristic, thus the conductive substrate 210 is electrically connected to a circuit board when this conventional LED 200 is disposed on the circuit board or other carrier; and the conventional LED 200 is electrically connected to the circuit board through the conductive wires (not shown) disposed on the contact pad 232.

As mentioned above, the method for fabricating the conventional LED 200 comprises the following steps. First, the doped semiconductor layer 226, the emitting layer 224 and the doped semiconductor layer 222 are sequentially formed on the aluminum oxide substrate (not shown). Then, a wafer bonding process is applied to bond the doped semiconductor layer 222 to the conductive substrate 210. Next, a laser lift-off process is applied to remove the aluminum oxide substrate. Finally, the pad 232 is formed, and the fabrication of the conventional LED 200 is totally completed.

In the conventional technique, the doped semiconductor layer 222 is bonded to the conductive substrate 210 by using a Pd—In solder. However, since a high temperature near 1000° C. is generated by the laser lift-off process and the Pd—In solder cannot sustain such high temperature, the adherence strength between the doped semiconductor 222 and the conductive substrate 210 is degraded.

### SUMMARY OF THE INVENTION

Therefore, it is an object of the present invention to provide a method for fabricating an LED having a better interface adherence strength.

In addition, it is another object of the present invention to provide an LED having a better interface adherence reliability.

In order to achieve the objects mentioned above and others, the present invention provides a method for fabricating an LED, and the method comprises the following steps. First, a first type doped semiconductor layer, an emitting layer and a second type doped semiconductor layer are sequentially formed on an epitaxy substrate. Then, a first transparent conductive layer is formed on the second type doped semiconductor layer. Next, a substitution substrate having a second transparent conductive layer formed thereon is provided. Then, a wafer bonding process is performed on the epitaxy substrate and the substitution substrate, so as to bond the first transparent conductive layer and the second transparent conductive layer. Finally, the epitaxy substrate is removed.

In accordance with a preferred embodiment of the present invention, a positive force applied during the wafer bonding process mentioned above is less than 10⁶ N.

In accordance with the preferred embodiment of the present invention, the temperature applied during the wafer bonding process mentioned above is between 20° C. and 1200° C.

In accordance with the preferred embodiment of the present invention, the wafer bonding process mentioned above is performed in the atmosphere or in the vacuum.

In accordance with the preferred embodiment of the present invention, the wafer bonding process mentioned above further comprises injecting a reaction gas. In addition, the reaction gas may be nitrogen or oxygen. Alternatively, the reaction gas may be composed of 5% hydrogen and 95% nitrogen.

In accordance with the preferred embodiment of the present invention, the method for removing the epitaxy substrate mentioned above comprises applying a laser lift-off process. In addition, the laser lift-off process may apply an Excimer Laser or an Nd-YAG Laser.

In accordance with the preferred embodiment of the present invention, before performing the wafer bonding process mentioned above, the method further comprises performing a hydrophilic process on the first transparent conductive layer and the second transparent conductive layer.

In accordance with the preferred embodiment of the present invention, before forming the first transparent conductive layer, the method further comprises forming an ohmic contact layer on the second type doped semiconductor layer.

In accordance with the preferred embodiment of the present invention, before forming the first type doped semiconductor layer, the method further comprises forming a buffer layer on the epitaxy substrate. In addition, the step of removing the substrate further comprises simultaneously removing the buffer layer.

In accordance with the preferred embodiment of the present invention, before forming the second transparent conductive layer, the method further comprises forming a reflecting layer on the substitution substrate.

In accordance with the preferred embodiment of the present invention, the thickness of the first transparent conductive layer mentioned above is from 50 Å (angstroms) to 4 μm.

In accordance with the preferred embodiment of the present invention, the thickness of the second transparent conductive layer mentioned above is from 50 Å to 4 μm.

In accordance with the preferred embodiment of the present invention, after removing the epitaxy substrate, the method further comprises forming a contact pad on the first type doped semiconductor layer.

In accordance with the preferred embodiment of the present invention, after removing the epitaxy substrate, the method further comprises removing a part of the first type doped semiconductor layer and the emitting layer to expose a partial surface of the second type doped semiconductor layer. Then, a first contact pad is formed on the first type doped semiconductor layer, and a second contact pad is formed on a part of the second type doped semiconductor layer that is not covered by the emitting layer.

In order to achieve the objects mentioned above and others, an LED is provided by the present invention. The LED comprises a substrate, a transparent conductive layer and a semiconductor layer. Wherein, the transparent conductive layer is disposed on the substrate, and the semiconductor layer is disposed on the transparent conductive layer. In addition, the semiconductor layer comprises a first type doped semiconductor layer, an emitting layer and a second type doped semiconductor layer. The first type doped semiconductor layer is disposed on the transparent conductive layer, and the emitting layer is disposed between the first type doped semiconductor layer and the second type doped semiconductor layer.

In accordance with the preferred embodiment of the present invention, the LED mentioned above further comprises an ohmic contact layer disposed between the transparent conductive layer and the semiconductor layer.

In accordance with the preferred embodiment of the present invention, the LED mentioned above further comprises a reflecting layer disposed between the transparent conductive layer and the substrate.

In accordance with the preferred embodiment of the present invention, the first type doped semiconductor layer mentioned above is an n-type doped semiconductor layer, and the second type doped semiconductor layer is a p-type doped semiconductor layer. Alternatively, the first type doped semiconductor layer mentioned above may be a p-type doped semiconductor layer, and the second type doped semiconductor layer may be an n-type doped semiconductor layer.

In accordance with the preferred embodiment of the present invention, the emitting layer mentioned above is a doped semiconductor layer composed of three or fourth chemical elements.

In summary, comparing to the conventional technique, since a bonding is formed between the transparent conductive layers in the present invention, an LED with better interface adherence reliability is provided by the present invention. Furthermore, the LED of the present invention further provides better light-emitting efficiency.

### BRIEF DESCRIPTION DRAWINGS

The accompanying drawings are included to provide a further understanding of the invention, and are incorporated in and constitute a part of this specification. The drawings illustrate embodiments of the invention, and together with the description, serve to explain the principles of the invention.

FIG. 1 is a schematic sectional view of a conventional LED.

FIG. 2 is a schematic sectional view of another conventional LED.

FIGS. 3A˜3D are the schematic sectional views illustrating a method for fabricating the LED according to a first preferred embodiment of the present invention.

FIGS. 4A˜4B are the schematic sectional views illustrating a method for fabricating the LED according to a second preferred embodiment of the present invention.

### DESCRIPTION PREFERRED EMBODIMENTS

### First Embodiment

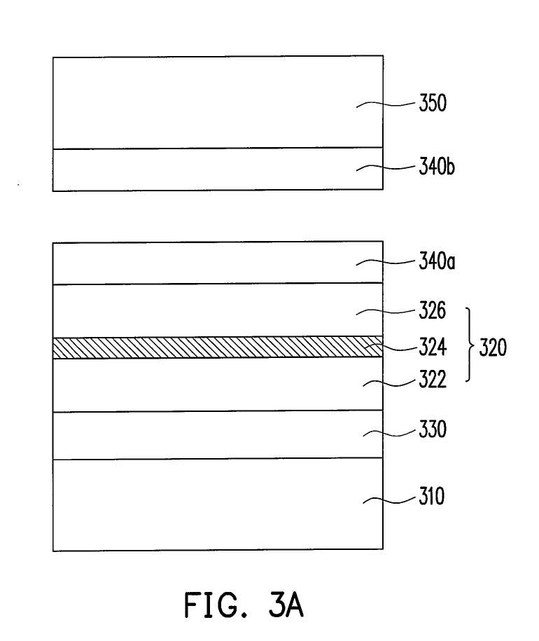

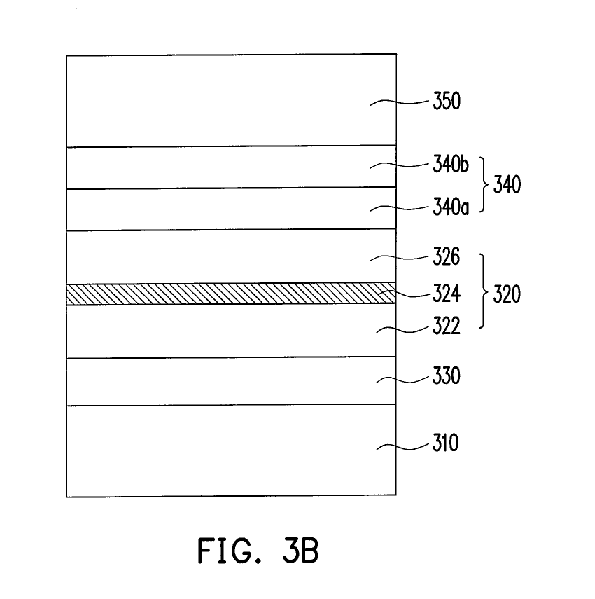

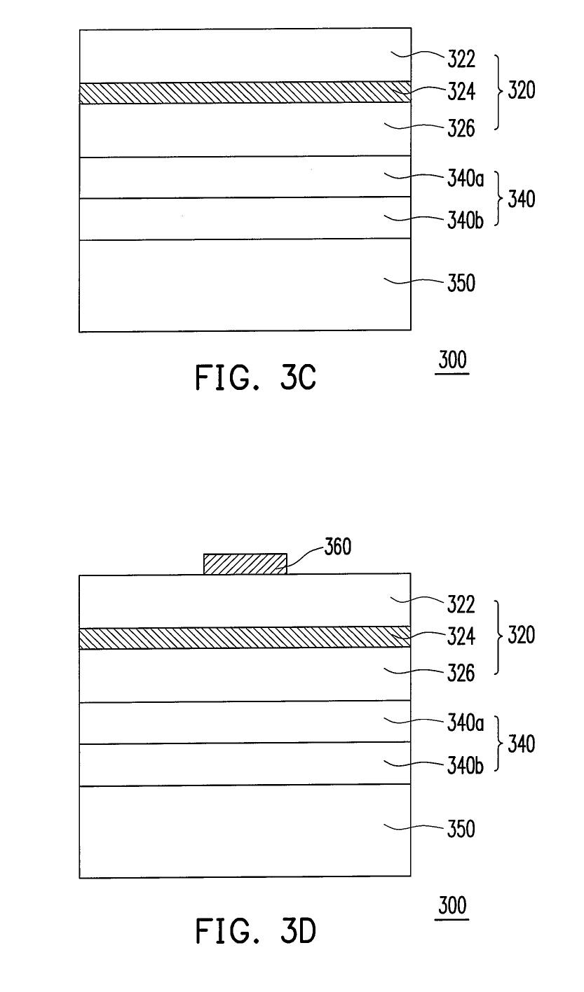

FIGS. 3A˜3D are the schematic sectional views illustrating a method for fabricating the LED according to a first preferred embodiment of the present invention. Referring to FIG. 3A, the method for fabricating the LED according of the present embodiment comprises the following steps. First, an epitaxy substrate 310 is provided; and a doped semiconductor layer 322, an emitting layer 324 and a doped semiconductor layer 326 are sequentially formed on the epitaxy substrate 310. In addition, the epitaxy substrate 310 may be made of a semi-conductive or non-semi-conductive material such as Si, Glass, GaAs, GaN, AlGaAs, GaP, SiC, InP, BN, Al₂O₃ or AlN. It is to be noted that in order to improve the electrical characteristic of the doped semiconductor layer 322, a buffer layer 330 may be formed on the epitaxy substrate 310 before the doped semiconductor layer 322 is formed.

Then, a transparent conductive layer 304a is formed on the second type doped semiconductor layer 326, and the transparent conductive layer 340a is formed by such as the e-beam evaporation process, the evaporation process, the sputtering process or other appropriate process. In addition, the thickness of the transparent conductive layer 340a is from 50 Å to 4 μm, and is preferably 100 nanometers. Moreover, the transparent conductive layer 340a is composed of 10% SnO₂ and 90% In₂O₃. In other words, the transparent conductive layer 340a is made of indium tin oxide (ITO). Alternatively, the transparent conductive layer 340a may be made of indium zinc oxide (IZO), aluminum zinc oxide (AZO) or other transparent conductive material.

Then, a substitution substrate 350 is provided; and a transparent conductive layer 340b is formed on the substitution substrate 350. Wherein, the substitution substrate 350 is made of Si, AlN, BeO, Cu, or other material with high electrical conductivity coefficient and high thermal conductive coefficient. In addition, the method for forming the transparent conductive layer 340a is similar to the method for forming the transparent conductive layer 340b. The thickness of the transparent conductive layer 340b is from 50 Å to 4 μm and preferably 100 nanometers. Moreover, the transparent conductive layer 340b is made of ITO, IZO, AZO or other transparent conductive material.

Referring to FIG. 3B, a wafer bonding process is applied on the epitaxy substrate 310 and the substitution substrate 350, such that the transparent conductive layer 340a is bonded to the transparent conductive layer 304b for forming a single transparent conductive layer 340. In other words, a bonding is formed by the transparent conductive layer 340a and the transparent conductive layer 340b with the wafer bonding process. Specifically, the positive force applied during the wafer bonding process is less than 10⁶ N, and is preferably 200 N. In addition, the temperature applied during the wafer bonding process is between 20° C. and 1200° C., and is preferably 600° C. Moreover, the wafer bonding process is performed in the atmosphere or in the vacuum. Alternatively, a reaction gas is injected during the wafer bonding process, and the reaction gas may be nitrogen, oxygen, or a combination gas of 5% hydrogen and 95% nitrogen. It is to be noted that in order to easily form the bonding from the transparent conductive layer 340a and the transparent conductive layer 340b, before performing the wafer bonding process, a hydrophilic process is performed on the first transparent conductive layer 340a and the second transparent conductive layer 340b.

Referring to FIG. 3C, after the wafer bonding process is completed, the epitaxy substrate 310 is removed, and the preliminary fabrication of the LED 300 is completed. In addition, a laser lift-off process may be used to remove the epitaxy substrate 310 in the present embodiment, and the laser lift-off process may apply an Excimer Laser. For example, the laser lift-off process may apply a KrF Excimer Laser with a wavelength of 248 nanometers. It is to be noted that if a buffer layer 330 is formed, the epitaxy substrate 310 and the buffer layer 330 should be removed at the same time.

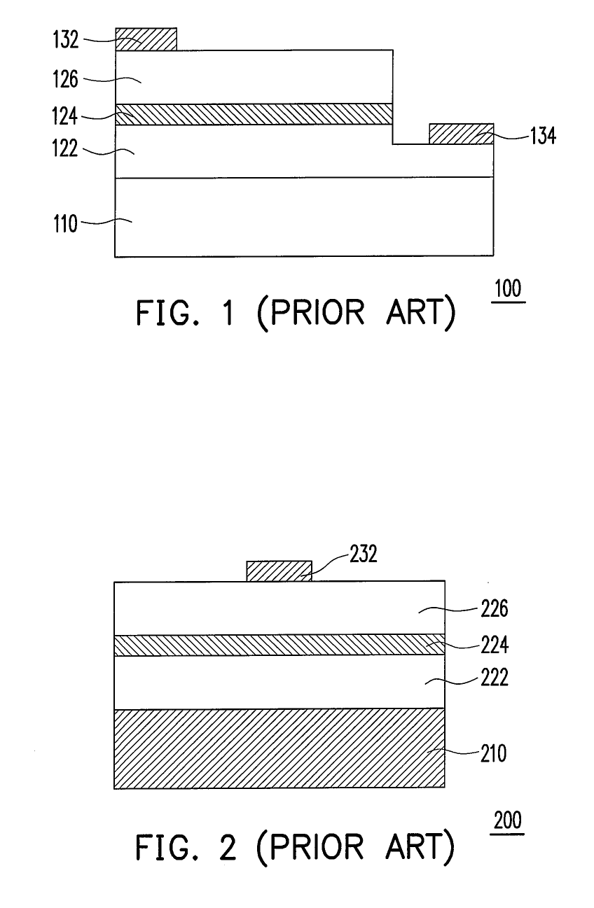

Referring to FIG. 3D, the structure formed by the manufacturing process mentioned above may be a flat LED (similar to the one shown in FIG. 1) or a vertical LED (similar to the one shown in FIG. 2). For fabricating the vertical LED, a contact pad 360 is formed on the doped semiconductor layer 322 after the epitaxy substrate 310 is removed. Moreover, the structure of the LED 300 is described in greater detail hereinafter.

Referring to FIG. 3D, the LED 300 comprises a substitution substrate 350, a transparent conductive layer 340 and a semiconductor layer 320. Wherein, the transparent conductive layer 340 is disposed between the substitution substrate 350 and the semiconductor layer 320. In addition, the semiconductor layer 320 comprises a doped semiconductor layer 322, a doped semiconductor layer 326 and an emitting layer 324 that is disposed between the doped semiconductor layers 322 and 326. Specifically, if the LED 300 is a vertical LED, the LED 300 further comprises a contact pad 360 that is disposed on the doped semiconductor layer 322. Moreover, the substitution substrate 350 is made of a conductive material.

Regarding to the semiconductor layer 320, if the doped semiconductor layer 322 is an n-type doped semiconductor layer, the doped semiconductor layer 326 should be a p-type doped semiconductor layer. Contrarily, if the doped semiconductor layer 322 is a p-type doped semiconductor layer, the doped semiconductor layer 326 should be an n-type doped semiconductor layer. Moreover, the material of the emitting layer 324 may contain a quantum well structure that is mainly composed of the III-V elements, such as GaN, GaAs, AlN, InGaN and AlGaN composed of three elements, or GaInAsN and GaInPN composed of four elements.

Comparing to the conventional technique where the bonding is made by the Pd—In solder, a bonding layer is formed by the transparent conductive layer 340a and the transparent conductive layer 340b in the present invention, such that the certain adherence strength between the transparent conductive layer 340a and the transparent conductive layer 340b is sustained after a high temperature laser lift-off process is performed. In other words, the LED 300 formed by the present invention has higher adherence strength and thermal stability. Furthermore, comparing to the conventional transparent conductive layer whose electrodes are made of thin metal such as Ni (nickel) and Au (gold), since the transparent conductive layer 340 provided by the present invention has better transparency, the LED 300 formed by the present invention has better electrical characteristics and light-emitting efficiency.

### Second Embodiment

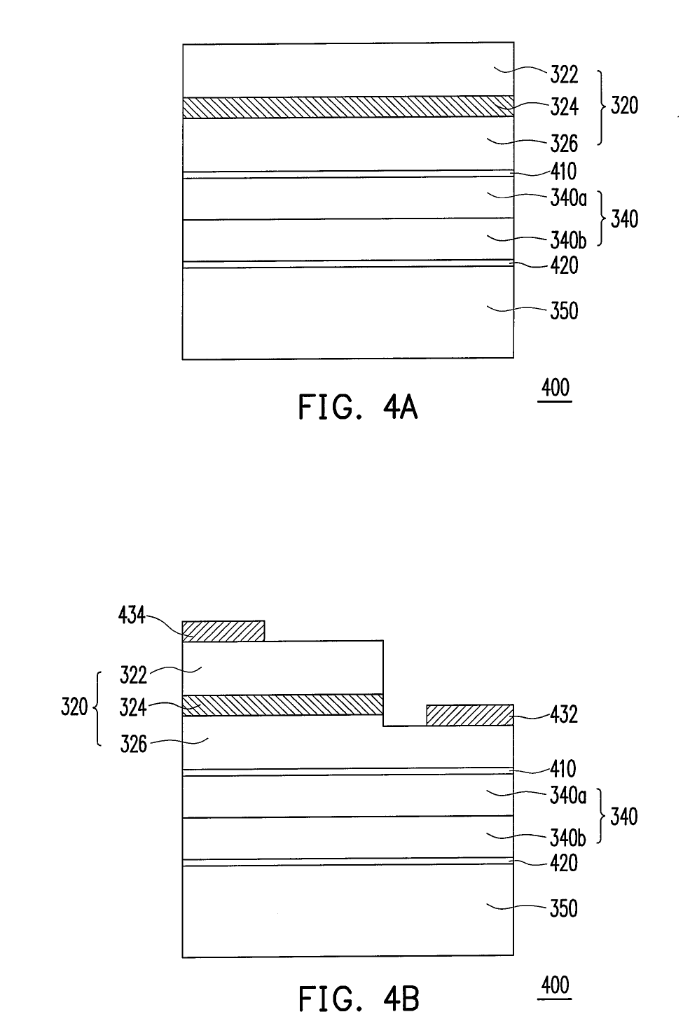

FIGS. 4A˜4B are the schematic sectional views illustrating a method for fabricating the LED according to a second preferred embodiment of the present invention. Referring to FIG. 4A, the second embodiment is similar to the first embodiment, and the difference is: in the method for fabricating the LED 400 of the second embodiment, in order to improve the electrical characteristic of the interface between the transparent conductive layer 340 and the doped semiconductor layer 326, before the transparent conductive layer 340a is formed, an ohmic contact layer 410 is formed on the doped semiconductor layer 326, such that the electrical characteristic of the interface between the transparent conductive layer 340a and the doped semiconductor layer 326 is improved. For example, if the doped semiconductor layer 326 is the p-doped semiconductor layer, the ohmic contact layer 410 may be made of NiO. In addition, in order to improve the light-emitting efficiency, before the transparent conductive layer 340b is formed, a reflecting layer 420 is formed on the substitution substrate 350. Moreover, the reflecting layer 420 is made of Al or Ag, and the reflecting layer 420 may be an aluminum layer of 120 nanometers.

Referring to FIG. 4B, the structure formed by the manufacturing process mentioned above may be a flat LED (similar to the one shown in FIG. 1) or a vertical LED (similar to the one shown in FIG. 2). For fabricating the flat LED, after the epitaxy substrate 310 is removed, a part of the doped semiconductor layer 322 and the emitting layer 324 are removed, so as to expose a partial surface of the doped semiconductor layer 326. Then, a contact pad 324 is formed on the doped semiconductor layer 322, and a contact pad 432 is formed on the doped semiconductor layer 326 that is not covered by the emitting layer 324, such that the fabrication of the LED 400 is completed.

It is to be noted that the structure shown in FIG. 3C may be fabricated as a flat LED, and the structure shown in FIG. 4A may be fabricated as a vertical LED.

In summary, the LED and the method for fabricating the LED provided by the present invention at least have the following advantages:

1. Comparing to the conventional technique, a bonding is formed by two transparent conductive layers in the present invention, thus the LED structure is placed on a substrate with higher electrical and thermal conductivity. Accordingly, the LED of the present invention has better adherence strength and higher thermal stability. Moreover, the LED of the present invention also has better electrical characteristics.

2. The method for fabricating the LED according to the present invention is compatible with the current fabricating process, thus it is not required to add additional fabricating equipment in the present invention.

Although the invention has been described with reference to a particular embodiment thereof, it will be apparent to one of the ordinary skill in the art that modifications to the described embodiment may be made without departing from the spirit of the invention. Accordingly, the scope of the invention will be defined by the attached claims not by the above detailed description.

What is claimed is:

1. A method for fabricating a light emitting diode (LED), comprising:
sequentially forming a first type doped semiconductor layer, an emitting layer and a second type doped semiconductor layer on an epitaxy substrate;
forming a first transparent conductive layer on the second type doped semiconductor layer;
providing a substitution substrate and forming a second transparent conductive layer on the substitution substrate;
performing a wafer bonding process on the epitaxy substrate and the substitution substrate so as to bond the first transparent conductive layer and the second transparent conductive layer; and removing the epitaxy substrate.

2. The method for fabricating the LED of claim 1, wherein a positive force applied during the wafer bonding process is less than 10⁶ N.

3. The method for fabricating the LED of claim 1, wherein the temperature applied during the wafer bonding process is between 20° C. and 1200° C.

4. The method for fabricating the LED of claim 1, wherein the wafer bonding process is performed in the atmosphere or in the vacuum.

5. The method for fabricating the LED of claim 1, wherein the wafer bonding process further comprises injecting a reaction gas.

6. The method for fabricating the LED of claim 5, wherein the reaction gas comprises nitrogen or oxygen.

7. The method for fabricating the LED of claim 5, wherein the reaction gas is composed of 5% hydrogen and 95% nitrogen.

8. The method for fabricating the LED of claim 1, wherein the method for removing the epitaxy substrate comprises using a laser lift-off process.

9. The method for fabricating the LED of claim 8, wherein the laser lift-off process comprises using an Excimer Laser or an Nd-YAG Laser.

10. The method for fabricating the LED of claim 1, wherein before the wafer bonding process is performed, the method further comprises performing a hydrophilic process on the first transparent conductive layer and the second transparent conductive layer.

11. The method for fabricating the LED of claim 1, wherein before the first transparent conductive layer is formed, the method further comprises forming an ohmic contact layer on the second type doped semiconductor layer.

12. The method for fabricating the LED of claim 1, wherein before the first type doped semiconductor layer is formed, the method further comprises forming a buffer layer on the epitaxy substrate.

13. The method for fabricating the LED of claim 12, wherein the step of removing the epitaxy substrate further comprises removing the buffer layer.

14. The method for fabricating the LED of claim 1, wherein before the second transparent conductive layer is formed, the method further comprises forming a reflecting layer on the substitution substrate.

15. The method for fabricating the LED of claim 1, wherein the thickness of the first transparent conductive layer is from 50 Å to 4 μm.

16. The method for fabricating the LED of claim 1, wherein the thickness of the first transparent conductive layer is from 50 Å to 4 μm.

17. The method for fabricating the LED of claim 1, wherein after removing the epitaxy substrate, the method further comprises forming a contact pad on the first type doped semiconductor layer.

18. The method for fabricating the LED of claim 1, wherein after removing the epitaxy substrate, the method further comprises:
removing a part of the first type doped semiconductor layer and the emitting layer, so as to expose a partial surface of the second type doped semiconductor layer;
forming a first contact pad on the first type doped semiconductor layer; and
forming a second contact pad on the second type doped semiconductor layer that is not covered by the emitting layer.

19. A light emitting diode (LED), comprising:
a substrate;
a transparent conductive layer disposed on the substrate; and
a semiconductor layer disposed on the transparent conductive layer comprising a first type doped semiconductor layer, an emitting layer and a second typed semiconductor layer, wherein the first type doped semiconductor layer is disposed on the transparent conductive layer, and the emitting layer is disposed between the first type doped semiconductor layer and the second type doped semiconductor layer.

20. The LED of claim 19, further comprising an ohmic contact layer disposed between the transparent conductive layer and the semiconductor layer.

21. The LED of claim 19, further comprising a reflecting layer disposed between the transparent conductive layer and the substrate.

22. The LED of claim 19, wherein the first type doped semiconductor layer is an n-type doped semiconductor layer, and the second type doped semiconductor layer is a p-type doped semiconductor layer.

23. The LED of claim 19, wherein the first type doped semiconductor layer is a p-type doped semiconductor layer, and the second type doped semiconductor layer is an n-type doped semiconductor layer.

24. The LED of claim 19, wherein the emitting layer is a doped semiconductor layer composed of three chemical elements or four elements.
